(19) United States
(12) Patent Application Publication
(10) Pub. No.: US 2004/0263076 A1
(43) Pub. Date: Dec. 30, 2004

(54) Light emitting display device with mechanical pixel switch

(76) Inventors: Siebe Tjerk De Zwart, Eindhoven (NL); Roy Van Dijk, Eindhoven (NL); Ramon Pascal Van Gorkom, Eindhoven (NL); Peter Alexander Duine, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/501,169

(22) PCT Filed: Dec. 23, 2002
(86) PCT No.: PCT/IB02/05703

(30) Foreign Application Priority Data
Jan. 15, 2002 (EP) 02075148.3

(51) Int. Cl. H01J 17/00

(52) U.S. Cl. 313/517

(57) ABSTRACT

A display device comprising a first and a second set of electrodes (2, 5), and a plurality of light-emitting elements (3), arranged between said sets of electrodes. The display further comprises an electromechanically operable foil (6), located between said light-emitting elements (3) and said second set of electrodes, with a conducting layer facing the light-emitting elements (3). The foil (6) is arranged to place the conducting layer (7) in contact with selected ones of said light-emitting elements (3), thereby closing a circuit from said first set of electrodes (2), via said elements (3), to said conducting layer (7). Thus, the foil acts as a plurality of “switches”, connecting selected light-emitting elements to the conducting layer. This function can be used for controlling the light-emitting elements with a higher degree of accuracy.

The present invention relates to a display device of the type in which a plurality of light-emitting elements is arranged between two sets of electrodes. In particular, the invention relates to an organic LED display, possibly a color display.

A drawback of the present-day Poly-LED and O-LED displays is that the LED layers have a comparatively large capacitance. This is caused by the fact that the LED layers are very thin (˜300 nm). For large displays, the capacitance hampers or even prohibits passive matrix operation, as the displacement currents become too large in comparison with the currents used to generate light in the LEDs. This results in inaccurate driving, power dissipation in the tracks and large currents in the drivers.

It is an object of the present invention to overcome these problems and to provide an improved LED display.

This and other objects are achieved by a display of the type mentioned in the opening paragraph, further comprising an electromechanically operable foil having at least one electrically conducting side, the foil being located between said light-emitting elements and said second set of electrodes, with the conducting side facing the light-emitting elements, and the foil being arranged to place the conducting side in contact with selected ones of said light-emitting elements, thereby closing a circuit from said first set of electrodes, via said elements, to said conducting side.

Thus, the foil acts as a plurality of “switches”, connecting selected light-emitting elements to the conducting side of the foil. This function can be used for controlling the light-emitting elements with a higher degree of accuracy.

Large-size LED displays are thereby obtained, without causing the problems traditionally associated with them. The foil switching also consumes little power in driving overhead, making the display more power efficient.

The entire foil may be made of an electrically conducting material. Alternatively, the foil is made of an insulating material having one side coated with a conducting layer.

According to one embodiment, the foil is displaceable towards electrically activated electrodes in said second set of electrodes, thereby moving the conducting layer away from said light-emitting elements. This feature can be used to separate the conducting layer from the light-emitting elements, and thereby interrupt any electric current flowing between the first electrodes and the conducting layer, via the light-emitting elements.

Furthermore, the foil is displaceable towards electrically activated electrodes in said first set of electrodes, thereby forcing the conducting layer against said light-emitting elements. This feature makes it possible to bring the conducting layer in electrical contact with the light-emitting elements.

Alternatively, or in combination, the foil may be arranged to be forced against said light-emitting elements except when attracted towards electrically activated electrodes in said second set of electrodes. In other words, the conducting layer is held in contact with the light-emitting elements, except in the areas corresponding to activated electrodes in the second set of electrodes. Therefore, there is no need to actively attract the foil towards the first set of electrodes.

According to a preferred embodiment, said first set of electrodes comprises a first plurality of parallel strip electrodes, and said second set of electrodes comprises a second plurality of parallel strip electrodes, in orthogonal relationship with said first plurality of electrodes, forming a grid of intersecting electrodes, and said light-emitting elements are located at intersections in this grid.

By activating selected ones of the orthogonal electrodes in the two sets, a specific light-emitting element can be activated. One way is to attract the foil towards all strips but one in the second set, and simultaneously attract the foil against one strip of the second set. This will bring only one intersection of the conducting layer in contact with a light-emitting element.

These and other aspects of the invention will be apparent from the preferred embodiments more clearly described with reference to the appended drawings.

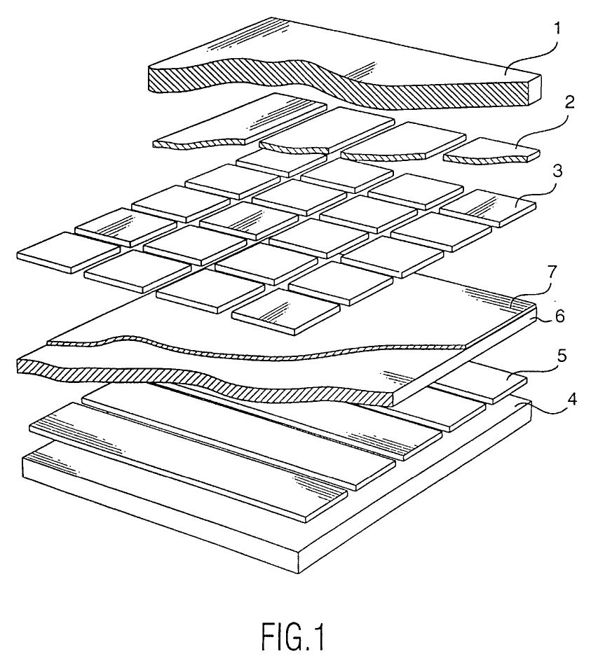

FIG. 1 is an exploded view of a LED display unit according to an embodiment of the invention.

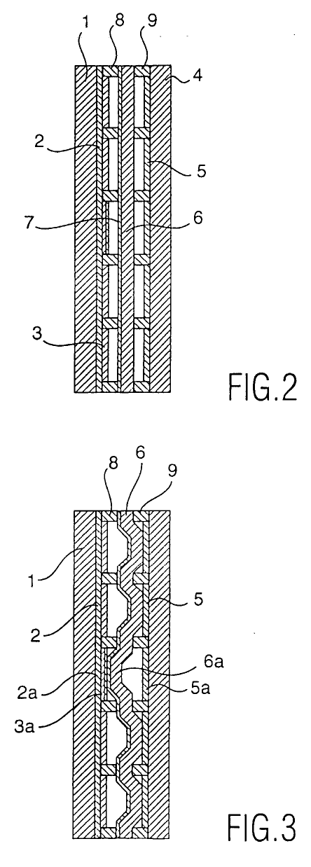

FIG. 2 is a sectional view of the display unit in FIG. 1 in the inactive state.

FIG. 3 is a sectional view of the display unit in FIG. 1 in the scanning state.

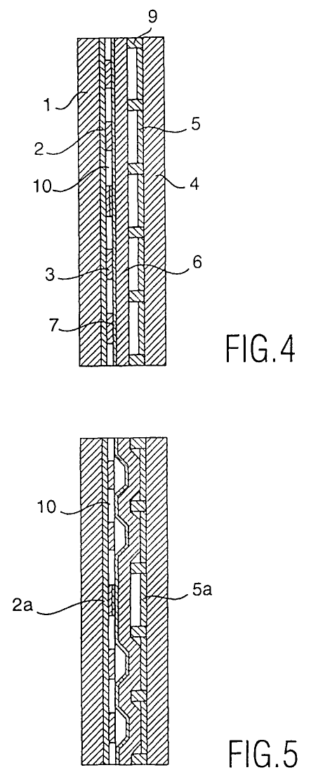

FIG. 4 is a sectional view of a display unit according to a second embodiment of the invention, in the inactive state.

FIG. 5 is a sectional view of the display unit in FIG. 4 in the scanning state.

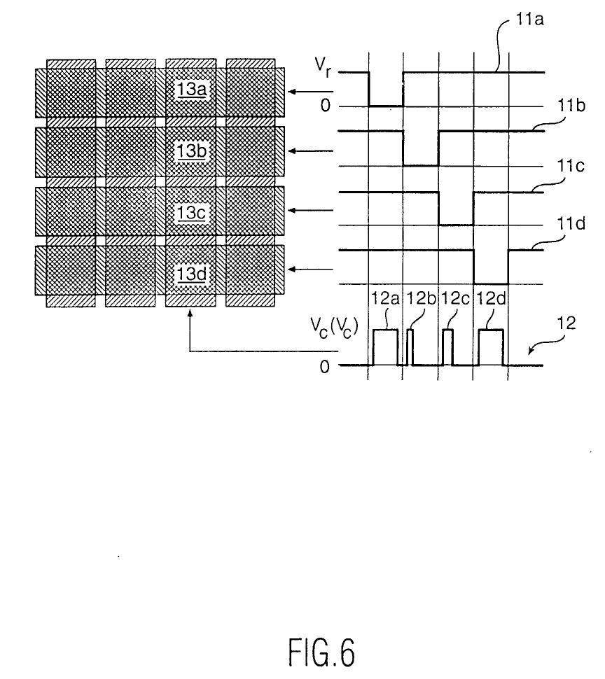

FIG. 6 is a diagram showing pulses for addressing a LED display unit.

With reference to FIG. 1, a display unit 10 comprises a front plate 1 on which a plurality of transparent column electrodes 2, such as ITO (Indium Tin Oxide) electrodes, is deposited. A plurality of light-emitting elements 3 is formed on the electrodes.

The light-emitting elements 3 may be organic electroluminescent devices, such as PolyLEDs (Polymer LEDs) or O-LEDs, but in principle also non-organic LEDs may be used. Even though the following description will be related primarily to PolyLEDs, this is not to be considered as a limitation of the disclosed invention.

PolyLEDs 3 consists of the mentioned ITO electrode layer (anode), a hole injection layer made of, for example, PEDOT/PPS (polyethylene dioxythiophene polystyrene sulphonate), a light emission layer made of, for example, PPV (polyphenylene vinylene), an injection layer (cathode) of e.g. Ba or alternative material, and a cover layer of e.g. Al or alternative material. The injection layer and the cover layer should be patterned in patches 3, each patch corresponding to one or more pixels and forming regular rows and columns on the surface of the front plate 1. It is these patches, i.e. in the illustrated example the LEDs except the electrode layer, that in the present document are referred to as light-emitting elements 3.

Furthermore, the display unit 10 comprises a back plate 4, provided with conductive row electrodes 5 for operating an electromechanically operable foil 6. The electrodes may be covered by an insulating layer. The electromechanically operable foil 6, made of e.g. an evaporable polymer such as parylene or polyimide, is arranged between the front plate and the back plate. The side of the foil 6 facing the front plate 1 and column electrodes 2 is coated with a conductive layer 7, made of e.g. Ag, Al, Au, etc. The conductive layer 7 may be unpatterned, i.e. cover the entire foil surface, but may also be patterned in a way corresponding to the LED pixels (or group of pixels). If the row electrodes are covered with an insulating layer, the entire foil 6 could optionally be made of conductive material.

In the example illustrated in FIGS. 2, 3, the foil is held in place by spacers 8, 9, on each side of the foil, making contact with the front and back plates 1, 4, respectively. The dimensions of the spacers on the front plate and the back plate may be of the order of 1 to 5 μm.

FIG. 2 shows the display in the inactive mode, i.e. when the power is turned off and all electrodes 2, 5 are at zero potential. FIG. 3 shows the same display during operation. In this case, a positive (or negative, depending on the characteristics of the foil 6) voltage is applied to the row electrodes 5. As a result, the foil 6 is attracted to the electrodes 5, and is forced towards, possibly against, the electrodes 5. The conductive layer 7 of the foil 6, referred to as the foil electrode, is grounded. Thereafter, one row 5a is selected by grounding the corresponding row electrode, so that the row section of the foil 6 adjacent to this row electrode is no longer forced towards the electrode 5a. Then, one column is selected by applying a positive (or negative) voltage to the corresponding column electrode 2a on the front plate 1. The area 6a of the foil corresponding to the intersection of the selected row 2a and column 5a will now be attracted to the column electrode 2a and forced towards and against the LED 3a located at this point. When the grounded foil electrode 7 makes contact with the LED 3a, a current flows from the column electrode 2a through the LED 3a and the grounded conductive layer 7 oil the foil 6.

As the current through the LED 3a will eliminate the potential difference between the foil electrode 7 and the LED 3a, it is possible that the attractive force will disappear so that the foil 6 is separated from the LED 3a. As soon as this happens, the LED 3a will again be charged through the column electrode 2, and the foil 6 is attracted again. In order to avoid such possible oscillatory behavior between the foil 6 and the column electrodes 2, or for any other reason, several alternative embodiments may be considered.

According to one such embodiment, a part of the LED area, e.g. the pixel sides, is replaced by insulating patches which are more or less equally thick as the LED layers. This area of the column electrodes is thus not brought into electrical contact with the conductive layer 7, thereby securing a certain attractive force at least around this area.

According to a further embodiment, illustrated in FIGS. 4, 5, the spacers 8 on the front plate side are removed, so that the foil 6 is held in contact with the LEDs 3 by the remaining spacers 9 in the inactive state, as shown in FIG. 4. When the display is activated, as shown in FIG. 5, the foil is attracted to the row electrodes 5, similarly as the display shown in FIG. 3. However, when a selected row electrode 5a is grounded, the row section of the foil 6 adjacent to the row electrode 5a will in this case be pushed against the column electrodes 2 of the front plate 1. The column electrodes 2 can now be used for activating selected pixels in this row of LEDs 3. As is shown in FIGS. 4, 5, the LEDs may be separated by an insulating area 10, facing the spacers 9. This insulating area prevents the conducting layer 7 from being in constant contact with the LEDs in these areas.

Also, materials with different work functions may be used for the foil electrode and the LED electrode, respectively. If these materials are electrically connected, a “vacuum level induced” electric field remains, resulting in a remaining attractive force, even when the LED is discharged through the conductive layer 7.

An example of a driving scheme is shown in FIG. 6. In this example, information is written line-at-a-time and the brightness is controlled by pulse-width modulation.

The voltage supplied to the four illustrated row electrodes is referred to as 11a-d. As is indicated by the division into time segments, the rows are placed at zero voltage potential one at a time. No modulation of these signals is necessary, as their only purpose is to “release” a particular row electrode at a certain time.

The voltage supplied to one of the four illustrated column electrodes is referred to as 12. As is indicated by the division into time segments, voltage pulses 12a-d of different width are fed to the electrode. The first pulse 12a will coincide with the signal 11a feeding a zero voltage to the upper row electrode, resulting in the LED 13a being activated. The second pulse 12b will similarly cause activation of the LED 13b, and so on.

Since the brightness of the LED is primarily determined by the current, it is advisable to use current-driving instead of voltage-driving. Instead of using fixed-current/pulse-width modulation, the brightness may also be controlled by using fixed-width/current modulation (“amplitude” modulation). To obtain more grey scales, a combination of pulse-width and pulse-height may be used. The switching voltages for the rows and columns may be of the order of 10 V. The switching time of the foil may be of the order of 1 μs, which is adequate for line-at-a-time driving.

A disadvantage of line-at-a-time driving is that the peak current through the LEDs is comparatively high. This can lower the efficiency. Driving the panel with subfield addressing, utilizing the memory properties of the foil might therefore be considered. In that case, the current can be more distributed with respect to time. However, a prerequisite is that a proper memory function is available (see above), and that the LED operates very homogeneously. In the case of subfield addressing, the current in the panel is shared by many pixels. In that case, inhomogeneities can lead to an unbalanced current distribution. In addition, the capacitive load of the drivers is dramatically increased during subframe addressing, because in the addressing cycle, parts of the rows already make contact with the foil. Although it is possible for subframe type addressing, the straightforward line-at-a-time scheme is preferred.

It should be noted that many modifications of the above-described preferred embodiments can be realized by those skilled in the art. For example, other suitable materials may be used for the foil or the electrodes. Also, the foil may be arranged in a different way between the electrodes, as long as the intended function is achieved. In principle, the invention can be implemented on any type of display based on the flow of current between two sets of electrodes, where it is desirable to achieve an improved addressing of the pixels.

1. A display device comprising
a first and a second set of electrodes (2, 5), and
a plurality of light-emitting elements (3), arranged between said sets of electrodes and being in electrical contact with said first set of electrodes (2), characterized by
an electromechanically operable foil (6) having at least one electrically conducting side (7),
said foil (6) being located between said light-emitting elements (3) and said second set of electrodes, with the conducting side facing the light-emitting elements (3), and
said foil (6) being arranged to place the conducting side (7) in contact with selected ones of said light-emitting elements (3), thereby closing a circuit from said first set of electrodes (2), via said elements (3), to said conducting side (7).

2. A display device as claimed in claim 1, wherein said foil (6) is made of an electrically conducting material.

3. A display device as claimed in claim 1, wherein said foil (6) has one side coated with an electrically conducting layer (7).

4. A display device as claimed in claim 1, wherein said foil (6) is displaceable towards electrically activated electrodes in said second set of electrodes (5), thereby moving the conducting side (7) away from said light-emitting elements (3).

5. A display device as claimed in claim 1, wherein said foil (6) is displaceable towards electrically activated electrodes in said first set of electrodes (2), thereby forcing the conducting side (7) against said light-emitting elements (3).

6. A display device as claimed in claim 1, wherein said foil (6) is arranged to be forced against said light-emitting elements except when attracted towards electrically activated electrodes in said second set of electrodes (5).

7. A display device as claimed in claim 1, wherein
said first set of electrodes (2) comprises a first plurality of parallel strip electrodes, and
said second set of electrodes (5) comprises a second plurality of parallel strip electrodes, in orthogonal relationship with said first plurality of electrodes,
so that said sets of electrodes form a grid of intersecting electrodes, and
wherein said light-emitting elements (3) are located at intersections of electrodes.

8. A display device as claimed in claim 1, wherein the conducting side (7) is connected to ground.

9. A display device as claimed in claim 1, wherein said light-emitting elements (3) are organic electroluminescent devices, such as O-LEDS or PolyLEDs.

10. A display device as claimed in claim 1, wherein said light-emitting elements (3) are non-organic LEDs.
